(19) United States
(12) Patent Application Publication
(10) Pub. No.: US 2015/0373856 A1
(43) Pub. Date: Dec. 24, 2015

(54) METHOD FOR FORMING BUMPS AND SUBSTRATE INCLUDING THE BUMPS

(71) Applicant: Samsung Electro-Mechanics Co., Ltd., Suwon-si (KR)

(72) Inventors: Cheol Ho CHOI, Hwaseong-si (KR); Chang Bo LEE, Suwon-si (KR); Chang Sup RYU, Yongin-si (KR)

(73) Assignee: SAMSUNG ELECTRO-MECHANICS CO., LTD., Suwon-si (KR)

(21) Appl. No.: 14/842,046

(22) Filed: Sep. 1, 2015

Related U.S. Application Data
(62) Division of application No. 13/487,926, filed on Jun. 4, 2012.

(30) Foreign Application Priority Data
Jul. 25, 2011 (KR) 10-2011-0073715

(51) Int. Cl. H05K 3/40

(52) U.S. Cl. CPC H05K 3/4007; H05K 2203/043; H05K 2203/041

(57) ABSTRACT

A method for forming bumps and a substrate including the bumps. The method includes: coating a solder resist on a substrate and electrodes formed on the substrate: performing laser etching treatment on the solder resist to form openings for forming bumps; printing a composition for forming bumps in the openings for forming bumps; and performing a reflowing process. Accordingly, the method can decrease the number of processes and realize a fine bump pitch of 90 μm or less at the time of forming bumps. Further, the method can also decrease the number of times that alignment is performed, due to the decrease in the number of processes.

### CROSS REFERENCE(S) TO RELATED APPLICATIONS

This application is a Divisional of U.S. application Ser. No. 13/487,926, filed on Jun. 4, 2012, which claims the benefit under 35 U.S.C. Section 119 of Korean Patent Application Serial No. 10-2011-0073715, entitled “Method for Forming Bumps and Substrate including the Bumps” filed on Jul. 25, 2011, which is hereby incorporated by reference in its entirety into this application.

### BACKGROUND OF THE INVENTION

1. Technical Field

The present invention relates to a method for forming bumps and a substrate including the bumps.

2. Description of the Related Art

There are a metal mask printing (MMP) method and a blue stencil printing (BSP) method in view of methods for forming bumps at the time of manufacturing a substrate. It has been known that, between them, the BSP method is more advantageous than the MMP method in embodying fine bump pitches. The reason is that the BSP method, in which an entrance of a bump ball is formed by exposure of dry film resist (DFR), is more advantageous than the MMP method, in which a predetermined size of metal mask is used for scale compensation.

The limit of bump pitch is about 100 μm in the BSP method, and a new method such as Cu post is required in order to further decrease the pitch. However, since the process of embodying the Cu post has many difficulties, development of the Cu post may take much time. One of the difficulties in the process exemplifies physical instability of a substrate that occurs when a solder resist is surface-treated with chemical copper, which is later removed.

A representative example of the method for forming bumps according to the related art will be described with reference to FIG. 1. The method employs a BSP method using DFR.

Referring to FIG. 1, copper foil pads 20 are formed on an outer layer of a substrate 10, and a solder resist (SR) 30 is formed on the copper foil pads 20. The solder resist 30 is selectively opened to expose the copper foil pads by performing exposing, developing, drying, and surface treating processes according to a pattern of a selected circuit mask. Then, a dry film resist 40 is coated on the resulting substrate, and subjected to exposing, developing, and drying processes again, thereby forming openings 41 for forming bumps. In addition, solder bumps 50 are formed in a BSP method. Finally, reflowing is performed, and the dry film is released, thereby forming a final bump.

As for the above method, exposing, developing, and drying processes are performed on the solder resist in order to define the openings 41, at which the solder bumps 50 are formed. Here, there is limitation in reducing a distance between adjacent solder bumps, that is, a pitch to 100 micrometers or smaller due to a resolving power limit in the developing process.

In addition, coating, exposing, developing, and drying processes are performed on the solder resist, and then coating, exposing, developing, and drying processes also need to be performed on the dry film. Since the entire procedure has a total of 12 steps which include SR coating→exposure→development→drying→surface treatment→DFR coating→exposure→development→drying→BSP→Reflow→DFR release, the procedure is very complicated, and thus, the costs rendered therein are problematic.

### SUMMARY OF THE INVENTION

An object of the present invention is to provide a method for forming bumps, capable of realizing a fine bump pitch in a comparatively simple way by decreasing the number of processes.

Another object of the present invention is to provide a substrate having various bump pitches by using the method.

According to an exemplary embodiment of the present invention, there is provided a method for forming bumps, including: coating a solder resist on a substrate and electrodes formed on the substrate: performing laser etching treatment on the solder resist to form openings for forming bumps; printing a composition for forming bumps in the openings for forming bumps; and performing a reflowing process.

The solder resist may include a carrier film.

The carrier film may be made of a material having a similar heat degradable property to the solder resist.

The laser etching treatment may be performed by removing the solder resist formed on the electrodes using laser, to form the openings for forming bumps.

The laser etching treatment may be performed such that a part of the solder resist, which is coated on the substrate, and a part of the solder resist, which is coated on both ends of each of the electrodes, is left.

The carrier film may be etched in the same size as the solder resist.

The carrier film may be removed more largely than the solder resist.

The composition for forming bumps may be printed by using blue stencil printing (BSP) or p-ball.

The solder resist may include a heat-curable resin, a light-curable resin, or a mixture resin of the heat-curable resin and the light-curable resin.

The method may further include releasing the carrier film from the solder resist.

The releasing of the carrier film may be performed by using a general DFR release process.

According to an exemplary embodiment of the present invention, there is provided a substrate including bumps formed by the above method.

The bump may be formed by etching the carrier film and the solder resist in the same size through the laser etching treatment, the bump having a linear shape in a height direction.

A top portion of the bump may be more largely tapered than any other portion of the bump.

The bump may have the same cross-sectional shape at any portion thereof.

The bump may be formed by etching the carrier film in a larger size than the solder resist through the laser etching treatment, the bump having a terrace structure.

### BRIEF DESCRIPTION OF THE DRAWINGS

FIG. 1 is a schematic view showing a procedure of forming bumps using a general BSP process;

FIG. 2 is a schematic view showing a procedure for forming bumps according to an exemplary embodiment of the present invention;

FIG. 3 is a schematic view showing a procedure of forming bumps using LDA depth control, according to another exemplary embodiment of the present invention; and

FIG. 4 is a schematic view showing a procedure for forming bumps according to an exemplary embodiment of the present invention.

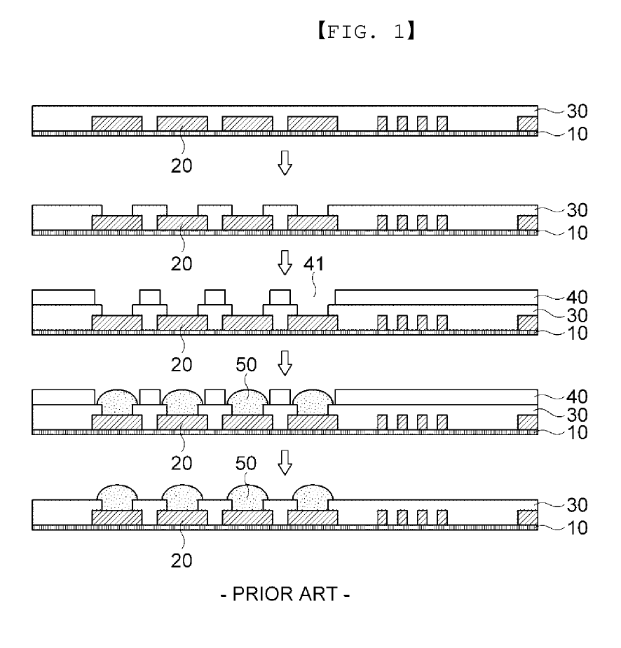

### DESCRIPTION OF THE PREFERRED EMBODIMENTS

Hereinafter, the present invention will be described in more detail.

Terms used in the present specification are for explaining the embodiments rather than limiting the present invention. Unless explicitly described to the contrary, a singular form includes a plural form in the present specification. Also, used herein, the word “comprise” and/or “comprising” will be understood to imply the inclusion of stated shapes, figures, steps, operations, constituents, elements and/or groups thereof but not the exclusion of any other shapes, figures, steps, operations, constituents, elements and/or groups thereof.

The present invention is directed to a method for forming bumps and a substrate including the bumps, capable of realizing a fine bump pitch with a shortened procedure as compared with the related art.

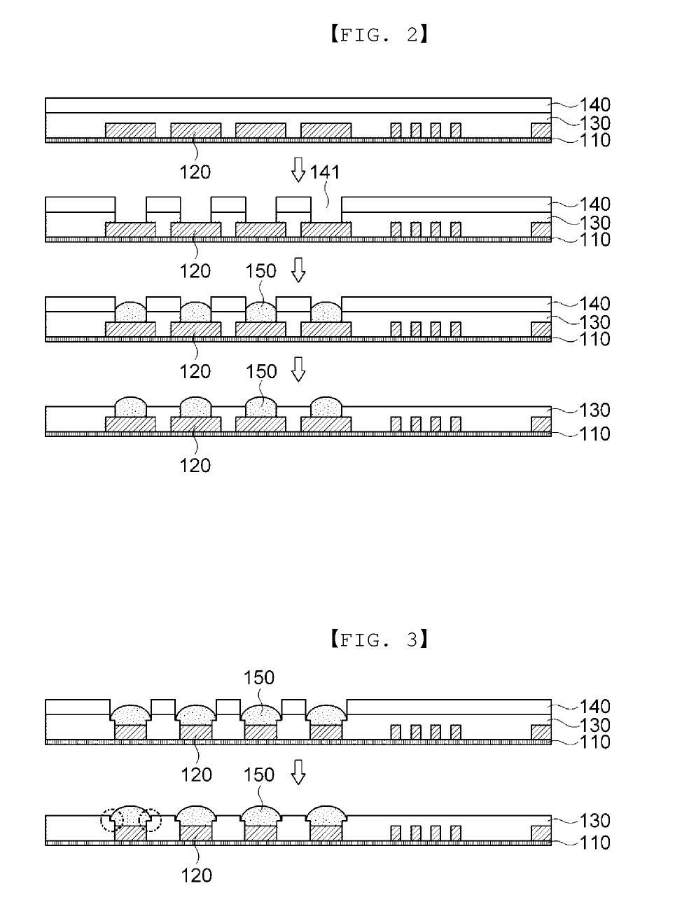

The method for forming bumps according to the present invention is as specifically shown in FIG. 2. Specifically, the method may include coating a solder resist on a substrate and electrodes formed on the substrate, performing laser etching treatment on the solder resist to form bumps, printing a composition for forming bumps, and performing reflowing.

The present invention will be described in detail with reference to FIG. 2. First, a solder resist 130 is coated on a substrate 110 and electrodes 120 formed on the substrate 110. The electrodes 120 may be generally made of copper, and may be spaced at a predetermined interval on the substrate 110.

The solder resist 130 is coated to cover the substrate 110 and the electrodes 120 formed on the substrate 110. In the present invention, examples of a material of the solder resist may include a heat-curable resin, a light-curable resin, and a mixture resin of the heat-curable resin and the light-curable resin, and are not particularly limited to the kind thereof.

Respective components constituting the solder resist are not particularly limited, and a general composition of the solder resist may be used.

The solder resist 130 of the present invention may further include a carrier film 140. In other words, the carrier film is made of a material having a similar heat degradable property to the solder resist, and may allow efficient processing at the time of laser etching. Specific examples of a material of the carrier film may include heat-resistant polymers, such as polyimide, polyethylene terephthalate, polyethylene terephthalate-polybutylene terephthalate copolymer, liquid crystal polymer (LCP), Teflon, and the like, but are not limited thereto.

Next, the solder resist 130 coated on the electrodes 120 may be selectively removed by laser treatment, to form openings 141 for forming bumps. In the present invention, at the time of laser treatment, as shown in FIG. 2, a part of the solder resist 130, which is coated on the substrate 110, and a part of the solder resist 130, which is coated on both ends of each of the electrodes 120, are left, and the other part of the solder resist 130 is removed. In other words, the laser treatment may be performed such that each of the openings 141 for forming bumps is positioned within an area of the electrode 120.

According to an exemplary embodiment of the present invention, in the case where the carrier film 140 is included in the solder resist 130, the carrier film 140 may have the same size as or a larger size than the solder resist by the laser etching treatment.

Here, the finally formed bump 150 has a linear shape in a height direction of the bump 150, as shown in FIG. 2. As such, the bump 150 has a linear type in which a top portion and a bottom portion are uniform, but the bump may not be at a completely 90 degree angle based on the substrate 110. That is to say, the top portion of the bump 150 may be somewhat largely tapered as shown in FIG. 4.

This is different from the related art where the bump 50 does not have a linear shape but a mushroom-like shape of which an upper portion is thicker. This characteristic of the present exemplary embodiment may result from the use of laser etching treatment. Therefore, according to the present exemplary embodiment, the finally formed bump 150 may have the same cross-sectional shape at any portion thereof.

The laser used in the present invention may be one selected from CO₂ laser, YAG laser, and Excimer laser. The laser having a shorter wavelength enables fine processing and thus may be preferable, but any one of the lasers may be selected depending on a predetermined size.

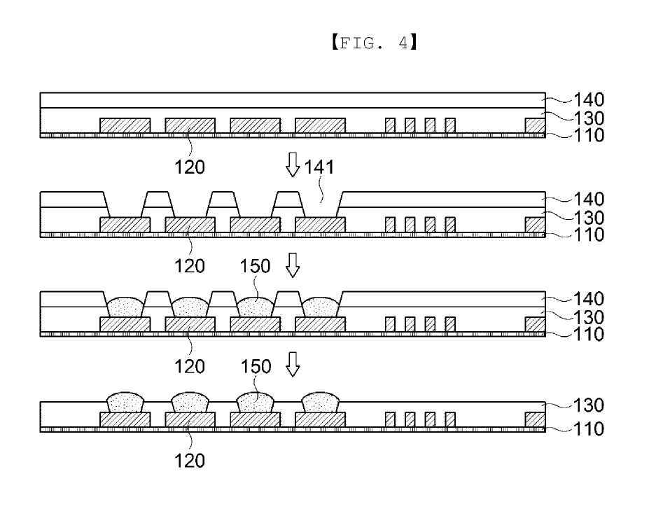

According to another exemplary embodiment of the present invention, as shown in FIG. 3, the carrier film 140 may be removed more largely than the solder resist 130. Here, the finally formed bumps 150 may have a terrace structure, and thus have a more stable shape.

In addition, the opening of the carrier film 140 is relatively larger than the opening of the solder resist, thereby allowing stable progress of a desmear process, which is a post process, and stable release of the carrier film.

The above stable structured bump shape can be obtained by finely regulating a depth of each of the openings for forming bumps trough laser etching treatment. In the present exemplary embodiment, only the terrace structure (circular portions in FIG. 3) is exemplified, but various bump shapes may be obtained.

After the laser etching treatment, conventional processes for manufacturing the substrate, such as desmear and surface treatment, may be performed, and specific methods and conditions thereof may follow conventional methods and conditions.

In addition, in the present invention, the composition for forming the bump 150 may be applied in the openings for forming bumps by using blue stencil printing (BSP), p-ball, or the like, but all may be used without particular limitation.

The composition may be applied in the openings for forming bumps by using blue stencil printing or p-ball, and passed through a reflow process. The reflow process also follows the conventional method, without particular limitation.

Finally, the carrier film is released. The carrier film may be released in a DFR release solution (sodium carbonate or aqueous solution) used in a general DFR process.

The method according to the present invention can decrease the number of processes as compared with the related art, and form fine bumps having 90 μm or less.

Meanwhile, in the related art, alignment needs to be considered twice when the opening of the solder resist is formed on the copper electrode pads and the opening of the dry film resist is formed on the solder resist.

Whereas, in the present invention, since alignment is considered once when the opening is formed on the copper electrode pads by laser etching treatment, the process can be shortened.

As set forth above, the present invention can decrease the number of processes and realize a fine bump pitch of 90 μm or less at the time of forming bumps. Further, the present invention can also decrease the number of times that alignment is performed, due to the decrease in the number of processes.

Further, the present invention can form bumps having various and desirable shapes through various laser etching methods since the bumps are formed by laser etching treatment.

While the present invention has been shown and described in connection with the embodiments, it will be apparent to those skilled in the art that modifications and variations can be made without departing from the spirit and scope of the invention as defined by the appended claims.

What is claimed is:

1. A method for forming bumps, comprising:
coating a solder resist on a substrate and electrodes formed on the substrate:
performing laser etching treatment on the solder resist to form openings for forming bumps;
printing a composition for forming bumps in the openings for forming bumps; and
performing a reflowing process.

2. The method according to claim 1, where the solder resist includes a carrier film.

3. The method according to claim 2, wherein the carrier film is made of a material having a similar heat degradable property to the solder resist.

4. The method according to claim 1, wherein the laser etching treatment is performed by removing a part of the solder resist formed on the electrodes using laser, to form the openings for forming bumps.

5. The method according to claim 1, wherein the laser etching treatment is performed such that a part of the solder resist, which is coated on the substrate, and a part of the solder resist, which is coated on both ends of each of the electrodes, are left.

6. The method according to claim 2, wherein the carrier film is etched in the same size as the solder resist through the laser etching treatment.

7. The method according to claim 2, wherein the carrier film is removed more largely than the solder resist.

8. The method according to claim 1, wherein the composition for forming bumps is printed by using blue stencil printing (BSP) or p-ball.

9. The method according to claim 1, wherein the solder resist includes a heat-curable resin, a light-curable resin, or a mixture resin of the heat-curable resin and the light-curable resin.

10. The method according to claim 1, further comprising releasing the carrier film from the solder resist.
